(19) United States
(12) Patent Application Publication
(10) Pub. No.: US 2026/0319306 A1
(43) Pub. Date: Oct. 15, 2026

(54) Dimming Device and Dimming Structure

(71) Applicants: BENING BOE SENSOR TECHNOLOGY CO., LTD., Beijing (CN); BOE TECHNOLOGY GROUP CO., LTD., Chaoyang District, Beijing (CN); BEIJING BOE TECHNOLOGY DEVELOPMENT CO., LTD., Beijing (CN)

(72) Inventors: Xiaoqian Ju, Beijing (CN); Xiaolong Wu, Beijing (CN); Chunlei Wang, Beijing (CN); Juan Chen, Beijing (CN); Changyin Wang, Beijing (CN); Zhan Li, Beijing (CN); Kun Yang, Beijing (CN)

(21) Appl. No.: 19/491,520

(22) PCT Filed: May 14, 2024
(86) PCT No.: PCT/CN2024/093219

§ 371 Date: Dec. 9, 2025

(30) Foreign Application Priority Data
Jun. 29, 2023 (CN) 202310790689.1

(51) Int. Cl. G02F 1/137; G02F 1/1335

(52) U.S. Cl. CPC G02F 1/137; G02F 1/133512; G02F 2202/04; G02F 2202/28

(57) ABSTRACT

A dimming device includes a first stacked structure, a second stacked structure, a second adhesive laver between the first and second stacked structures, an adhesive frame and at least one sealing block. The first stacked structure includes a first sobstrate, a first adhesive layer and a first functional laver. The second stacked structure, on a side of the first substrate proximate to the first adhesive laver, includes a second substrate. The adhesive frame, between the first and second substrates, sumounds the first functional layer and the second adhesive layer. The adhesive frame has at least one first opening whose projection along a first direction at least partially overlapping with a projection of the second adhesive laver along the first direction, the first direction being perpendicular to a side surface of the adhesive frame where the at least one first opening is located. Each sealing block is in a first opening.

### CROSS-REFERENCE TO RELATED APPLICATIONS

This application is the United States national phase of International Patent Application No. PCT/CN2024/093219, filed May 14, 2024, and claims priority to Chinese Patent Application No. 202310790689.1, filed Jun. 29, 2023, the disclosures of which are hereby incorporated by reference in their entireties.

### BACKGROUND OF THE INVENTION

### Field of the Invention

The present disclosure relates to the field of dimming technology, and in particular, to a dimming device, a manufacturing method, and a dimming structure.

### Description of Related Art

Laminated glass is a composite glass product consisting of two or more pieces of glass and one or more organic polymer interlayers located between the glass. After undergoing special high-temperature and pre-pressing (or vacuuming) processing and high-temperature and high-pressure processing, the glass and the interlayer are permanently bonded together. The laminated glass can withstand external impacts of a certain energy or temperature changes without breaking. Even if the laminated glass breaks, the fragments will stick to the interlayer and are not likely to hurt people, thus providing a certain degree of safety. Therefore, the laminated glass is widely used in construction, transportation and other fields.

### SUMMARY OF THE INVENTION

In an aspect, a manufacturing method for a dimming device is provided. The method includes: forming a first stacked structure, the first stacked structure including a first substrate, a first adhesive layer and a first functional layer disposed in stack; forming an adhesive frame on a side of the first stacked structure, where the adhesive frame is located on a side of the first substrate proximate to the first functional layer and surrounds the first functional layer, and the adhesive frame has at least one first opening; attaching a second stacked structure to a side of the adhesive frame away from the first substrate, where the second stacked structure and the first stacked structure are provided with a first gap therebetween, and the at least one first opening communicates with the first gap; laminating the first stacked structure, the adhesive frame, and the second stacked structure, to enable the first adhesive layer to bond the first substrate and the first functional layer, and the adhesive frame to bond the first stacked structure and the second stacked structure; injecting a liquid adhesive into the first gap through the at least one first opening; and solidifying the liquid adhesive to form a second adhesive layer; where the second adhesive layer bonds the first stacked structure and the second stacked structure.

In some embodiments, an orthographic projection of the first adhesive layer on a reference surface is located within an orthographic projection of the first substrate on the reference surface, and has a spacing from a boundary of the orthographic projection of the first substrate; the orthographic projection of the first adhesive layer on the reference surface coincides with an orthographic projection of the first functional layer on the reference surface; and along a direction perpendicular to the reference surface, a thickness of the adhesive frame is greater than a sum of a thickness of the first adhesive layer and a thickness of the first functional layer; where the reference surface is parallel to a surface of the first substrate proximate to the first functional layer. The manufacturing method further includes, between forming the first stacked structure and forming the adhesive frame on the side of the first stacked structure: applying pressure to the first stacked structure to remove air between the first adhesive layer and the first substrate; and laminating the first stacked structure to enable the first adhesive layer to bond the first substrate and the first functional layer.

In some embodiments, an orthographic projection of the first adhesive layer on a reference surface coincides with an orthographic projection of the first substrate on the reference surface, and an orthographic projection of the first functional layer on the reference surface is located within the orthographic projection of the first adhesive layer on the reference surface and has a spacing from a boundary of the orthographic projection of the first adhesive layer; and along a direction perpendicular to the reference surface, a thickness of the adhesive frame is greater than a thickness of the first functional layer; where the reference surface is parallel to a surface of the first substrate proximate to the first functional layer.

In some embodiments, the first stacked structure further includes a second functional layer and a third adhesive layer, the second functional layer being located on a side of the first functional layer away from the first substrate, and the third adhesive layer being located between the first functional layer and the second functional layer.

In some embodiments, the second stacked structure includes a second substrate, a fourth adhesive layer and a third functional layer disposed in stack; and an orthographic projection of the fourth adhesive layer on a reference surface is located within an orthographic projection of the second substrate on the reference surface and has a spacing from a boundary of the orthographic projection of the second substrate, and the orthographic projection of the fourth adhesive layer on the reference surface coincides with an orthographic projection of the third functional layer on the reference surface; where the reference surface is parallel to a surface of the first substrate proximate to the first functional layer. The manufacturing method further includes, between forming the adhesive frame on the side of the first stacked structure and attaching the second stacked structure to the side of the adhesive frame away from the first substrate: applying pressure to the second stacked structure to remove air between the fourth adhesive layer and the second substrate; and laminating the second stacked structure to enable the fourth adhesive layer to bond the second substrate and the third functional layer.

In another aspect, a dimming device is provided. The dimming device includes a first stacked structure, a second stacked structure, a second adhesive layer, an adhesive frame, and at least one sealing block. The first stacked structure includes a first substrate, a first adhesive layer and a first functional layer disposed in stack. The second stacked structure is located on a side of the first substrate proximate to the first adhesive layer, and the second stacked structure includes a second substrate. The second adhesive layer is located between the first stacked structure and the second stacked structure, and is configured to bond the first stacked structure and the second stacked structure. The adhesive frame is located between the first substrate and the second substrate and surrounds the first functional layer and the second adhesive layer. The adhesive frame has at least one first opening, a projection of the at least one first opening along a first direction at least partially overlaps with a projection of the second adhesive layer along the first direction; where the first direction is perpendicular to a side surface of the adhesive frame where the at least one first opening is located. Each sealing block in the at least one sealing block is located in a first opening in the at least one first opening and seals the first opening.

In some embodiments, a thickness of the first adhesive layer is M×d₁, and a thickness of the adhesive frame is N×d₂; where M and N are both positive integers less than 6, and N is greater than M; d₁ and d₂ range from 0.3 mm to 0.5 mm, and d₁ is less than or equal to d₂.

In some embodiments, a thickness of the first functional layer is d₃, and d₃ is less than or equal to 1.1 mm; and a thickness of the second adhesive layer is N×d₂-M×d₁-d₃.

In some embodiments, a material of the adhesive frame is same as a material of the first adhesive layer and different from a material of the sealing block, and the material of the first adhesive layer is different from a material of the second adhesive layer.

In some embodiments, an orthographic projection of the first adhesive layer on a reference surface is located within an orthographic projection of the first substrate on the reference surface and has a spacing from a boundary of the orthographic projection of the first substrate, and the orthographic projection of the first adhesive layer on the reference surface coincides with an orthographic projection of the first functional layer on the reference surface; and the adhesive frame abuts against the first substrate; where the reference surface is parallel to a surface of the first substrate proximate to the first functional layer.

In some embodiments, an orthographic projection of the first adhesive layer on a reference surface coincides with an orthographic projection of the first substrate on the reference surface, and an orthographic projection of the first functional layer on the reference surface is located within the orthographic projection of the first adhesive layer on the reference surface and has a spacing from a boundary of the orthographic projection of the first adhesive layer; and the adhesive frame abuts against the first adhesive layer; where the reference surface is parallel to a surface of the first substrate proximate to the first functional layer.

In some embodiments, the first functional layer is a dimming functional layer configured to adjust light transmittance, and a material of the first adhesive layer is polyvinyl butyral (PVB) or sentry glass plus (SGP); or the first functional layer is a display functional layer configured to display images, and a material of the first adhesive layer is optically clear adhesive (OCA), optical clear resin (OCR), or ethylene vinyl acetate (EVA).

In some embodiments, the first stacked structure further includes a second functional layer and a third adhesive layer. The second functional layer is located on a side of the first functional layer away from the first substrate. The third adhesive layer is located between the first functional layer and the second functional layer, and configured to bond the first functional layer and the second functional layer.

In some embodiments, the second stacked structure further includes: a fourth adhesive layer located on a side of the second substrate proximate to the second adhesive layer.

In some embodiments, an orthographic projection of the fourth adhesive layer on a reference surface coincides with an orthographic projection of the second substrate on the reference surface, and the adhesive frame abuts against the fourth adhesive layer; where the reference surface is parallel to a surface of the first substrate proximate to the first functional layer.

In some embodiments, an orthographic projection of the fourth adhesive layer on a reference surface is located within an orthographic projection of the second substrate on the reference surface, and has a spacing from a boundary of the orthographic projection of the second substrate; the orthographic projection of the fourth adhesive layer on the reference surface coincides with an orthographic projection of the second adhesive layer on the reference surface; and the adhesive frame abuts against the second substrate; where the reference surface is parallel to a surface of the first substrate proximate to the first functional layer.

In some embodiments, the second stacked structure further includes: a third functional layer, located on a side of the fourth adhesive layer away from the second substrate, where the adhesive frame further surrounds the third functional layer.

In some embodiments, the dimming device further includes: a first light-shielding layer and a second light-shielding layer. The first light-shielding layer is located on a side of the first substrate away from the second substrate and arranged along an edge of the first substrate, where of an orthographic projection of the first light-shielding layer on the first substrate, an outer boundary coincides with a boundary of the first substrate, and an inner boundary of the first light-shielding layer is located within an inner boundary of an orthographic projection of the adhesive frame on the first substrate. The second light-shielding layer is located on a side of the second substrate proximate to the first substrate and arranged along an edge of the second substrate, where at least a portion of the second light-shielding layer is located between the second substrate and the adhesive frame.

In some embodiments, the first functional layer includes a flexible circuit board, and the flexible circuit board and the first opening are located on a same side of the adhesive frame.

In some embodiments, the first functional layer includes a flexible circuit board, and the adhesive frame further has at least one second opening. The at least one first opening and the at least one second opening are located on a same side of the flexible circuit board; or the at least one first opening is located on one side of the flexible circuit board, and the at least one second opening is located on opposite side of the flexible circuit board.

In some embodiments, the first stacked structure includes a plurality of first functional layers, and the plurality of first functional layers are all bonded to the first adhesive layer; and two adjacent first functional layers in the plurality of first functional layers are provided with a spacing therebetween.

In some embodiments, the dimming device further includes: a limiting strip, a portion of the limiting strip being located in the spacing between the two adjacent first functional layers, where the limiting strip and the second stacked structure are provided with a spacing therebetween.

In some embodiments, the dimming device further includes: a limiting strip, a portion of the limiting strip being located in the spacing between the two adjacent first functional layers, where the limiting strip is in contact with the second stacked structure; and the limiting strip has a plurality of third openings, and at least one of the third openings is located between the two adjacent first functional layers.

In some embodiments, along a second direction, a dimension of the first opening is less than or equal to half a dimension of the first substrate, where the second direction is parallel to the side surface of the adhesive frame where the first opening is located.

In yet another aspect, a dimming structure is provided. The dimming structure includes the dimming device as described in any of the above embodiments; and the dimming structure is one of a curtain wall, a lighting roof, a rail transportation vehicle, and a passenger vehicle.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 to FIG. 6 are diagrams showing manufacturing steps of a manufacturing method for a dimming device, in accordance with some embodiments;

FIG. 7 is a structural diagram of a dimming device, in accordance to some embodiments;

FIG. 8 is a structural diagram of a first functional layer, in accordance with some embodiments;

FIG. 9 is another structural diagram of a first functional layer, in accordance with some embodiments;

FIG. 10 is a structural diagram of an adhesive frame including a plurality of sub-layers, in accordance with some embodiments;

FIG. 11 is a structural diagram showing a relative position of a first opening and a flexible circuit board, in accordance with some embodiments;

FIG. 12 is a structural diagram showing another relative position of a first opening and a flexible circuit board, in accordance with some embodiments;

FIG. 13 is a structural diagram showing yet another relative position of a first opening and a flexible circuit board, in accordance with some embodiments;

FIG. 14 is a structural diagram showing a relative position of a first opening, a second opening and a flexible circuit board, in accordance with some embodiments;

FIG. 15 is a structural diagram showing another relative position of a first opening, a second opening and a flexible circuit board, in accordance with some embodiments;

FIG. 16 is a structural diagram showing the position of a baffle, in accordance with some embodiments;

FIG. 17 is a diagram showing a manufacturing step for sealing a first opening, in accordance with some embodiments;

FIG. 18 is another structural diagram of a dimming device, in accordance to some embodiments;

FIG. 19 is a structural diagram showing the application of force to a first stacked structure, in accordance with some embodiments;

FIG. 20 is a structural diagram of a first stacked structure including a first functional layer and a second functional layer, in accordance with some embodiments;

FIG. 21 is a structural diagram of a dimming device including a second adhesive layer, in accordance with some embodiments;

FIG. 22 is a structural diagram of a fourth adhesive layer and a second substrate that are flush with each other, in accordance with some embodiments;

FIG. 23 is a structural diagram of a second stacked structure including a third functional layer, in accordance with some embodiments;

FIG. 24 is a structural diagram showing the application of force to a second stacked structure, in accordance with some embodiments;

FIG. 25 is a structural diagram showing the formation of a first light-shielding layer and a second light-shielding layer, in accordance with some embodiments;

FIG. 26 is a diagram showing of manufacturing steps of a first light-shielding layer and a second light-shielding layer, in accordance with some embodiments;

FIG. 27 is a structural diagram of a dimming device including a plurality of first functional layers, in accordance with some embodiments;

FIG. 28 is a cross-sectional view along the section line C-C in FIG. 27;

FIG. 29 is a structural diagram of a dimming device including a limiting strip, in accordance to some embodiments;

FIG. 30 is a cross-sectional view along the section line D-D in FIG. 29;

FIG. 31 is a structural diagram of a limiting strip provided with third openings, in accordance to some embodiments;

FIG. 32 is a cross-sectional view along the section line E-E in FIG. 31; and

FIG. 33 is a structural diagram of an automobile, in accordance with some embodiments.

### DESCRIPTION OF THE INVENTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on the embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” and “multiple” each mean two or more unless otherwise specified.

Some embodiments may be described using the term “connected” and its derivatives. The term “connected” should be understood in a broad sense, for example, the term “connected” may represent a fixed connection, or a detachable connection, or a one-piece connection; alternatively, the term “connected” may represent a direct connection, or an indirect connection through an intermediate medium. The embodiments disclosed herein are not necessarily limited to the context herein.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation, or other action that is “based on” one or more of the stated conditions or values may, in practice, be based on additional conditions or values exceeding those stated.

The terms “parallel,” “perpendicular” and “equal” as used herein include the stated conditions and the conditions similar to the stated conditions, and the range of the similar conditions is within the acceptable deviation range, where the acceptable deviation range is determined by a person of ordinary skill in the art in consideration of the measurement in question and the error associated with the measurement of a specific quantity (i.e., the limitation of the measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

The directional terms such as “up/on,” “down/under,” “left,” and “right” described in the embodiments of the present disclosure are described from the perspective shown in the drawings and should not be understood as limitations on the embodiments of the present disclosure In addition, it will be further understood in the context that when an element is referred to as being connected “on” or “under” another element, it can not only be directly connected “on” or “under” the another element, but may also be indirectly connected “on” or “under” the another element through an intermediate element.

In the related art, a dimming device may be formed using the following manufacturing process: an initial dimming device is formed first, the initial dimming device includes a first substrate, a first adhesive layer, a first functional layer, a second adhesive layer and a second substrate disposed in stack; and the initial dimming device further includes an adhesive frame surrounding the first functional layer; then the initial dimming device is laminated to form the dimming device. Since at least one of the first adhesive layer and the second adhesive layer may have inconsistent thickness, but during the laminating process, there is no gap between the first functional layer and the first substrate, and there is no gap between the first functional layer and the second substrate, resulting in the first functional layer not being able to deform accordingly with changes in the thickness of the first adhesive layer and/or the second adhesive layer. In this way, the stress applied by the first adhesive layer and/or the second adhesive layer on the first functional layer cannot be released, causing some regions of the first functional layer to bear heavier stress while some regions bear lighter stress, resulting in Mura phenomena in the first functional layer. For example, the first functional layer is a dye liquid crystal dimming functional layer, and materials of the first adhesive layer and the second adhesive layer are polyvinyl butyral (PVB). The laminating conditions for the initial dimming device are high temperature and high pressure. PVB exhibits fluidity at high temperature, which may cause the thickness of at least one of the first adhesive layer and the second adhesive layer to be inconsistent, thereby leading to uneven stress distribution in the dye liquid crystal dimming functional layer. Liquid crystal molecules in the region with heavier force in the dye liquid crystal dimming functional layer move to the region with lighter force. As a result, the liquid crystal molecules accumulate in the region with lighter force, resulting in black spots on the dye liquid crystal dimming functional layer. Here, the laminating is that: a first substrate (first film layer) is provided on one side of an adhesive layer and a second substrate (second film layer) is provided on the other side of the adhesive layer; and after undergoing special high-temperature pre-pressing (or vacuuming) and high-temperature and high-pressure processing via the adhesive layer, the first substrate (first film layer), the adhesive layer, and the second substrate (second film layer) are permanently bonded into a single piece. For example, materials of the first substrate and the second substrate are tempered glass, and the tempered glass may be flat glass, single-curved glass, or double-curved glass. The inventors have discovered that in a case where the first substrate is double-curved glass, the Mura phenomenon of the dimming device is more obvious. Here, the single-curved glass refers to glass having a curvature in a third direction, and the double-curved glass refers to glass having a curvature in the third direction and having a curvature in a fourth direction, where the third direction intersects the fourth direction, for example, the third direction is perpendicular to the fourth direction.

To solve the aforementioned problems, the embodiments of the present disclosure provide a manufacturing method for a dimming device 100, which includes steps (S100 to S600).

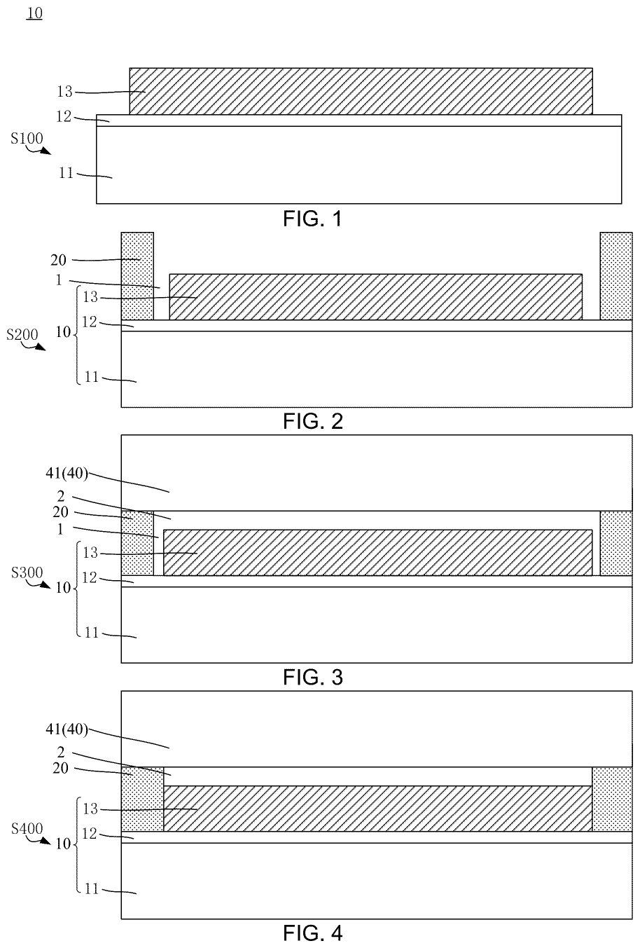

As shown in FIG. 1, in S100, a first stacked structure 10 is formed.

The first stacked structure 10 includes a first substrate 11, a first adhesive layer 12 and a first functional layer 13 disposed in stack. A material of the first substrate 11 may include a rigid material or a flexible material with a high light transmittance (such as a light transmittance greater than 85%).

As shown in FIG. 2, in S200, an adhesive frame 20 is formed on a side of the first stacked structure 10.

The first adhesive layer 12 may include a plurality of adhesive layers disposed in stack, that is, a thickness of the first adhesive layer 12 is M×d, where M is the number of the adhesive layers and d is a thickness of the adhesive layer. The number of the adhesive layers is less than six. For example, the number of the adhesive layers ranges from one to three, that is, M ranges from 1 to 3. For example, the number of the adhesive layers is one or three, which is not enumerated one by one in the embodiments of the present disclosure. The thickness of the adhesive layer ranges from 0.3 mm to 0.5 mm. For example, the thickness of the adhesive layer is 0.3 mm, 0.35 mm, 0.38 mm, 0.4 mm, 0.45 mm, 0.48 mm, or 0.5 mm, which is not enumerated one by one in the embodiments of the present disclosure.

The thickness of the first functional layer is d₃, where d₃ is less than or equal to 1.1 mm. For example, d₃ is 1.1 mm, 1 mm, 0.78 mm, 0.38 mm, or 0.15 mm, which is not enumerated one by one in the embodiments of the present disclosure.

An end of the adhesive frame 20 away from the first substrate 11 is farther away from the first substrate 11 than an end of the first functional layer 13 away from the first substrate 11. That is, along a thickness direction of the first stacked structure 10, the upper surface of the adhesive frame 20 is higher than the upper surface of the first functional layer 13. In this way, in one aspect, in the subsequent process of attaching a second stacked structure, the adhesive frame 20 enables the first stacked structure 10 and the second stacked structure to be provided with a first gap therebetween. In another aspect, a portion of the adhesive frame 20 surrounding the first functional layer 13 is relatively large, which may further reduce the risk of water vapor entering the first functional layer 13. The adhesive frame 20 has at least one first opening 21.

In some embodiments, as shown in FIG. 2, the adhesive frame 20 and the first functional layer 13 are provided with a deformation gap 1 therebetween. The deformation gap 1 provides accommodation space for the thermal expansion and contraction of the first functional layer 13, thereby reducing the risk of damage to the first functional layer 13 caused by mutual compression between the first functional layer 13 and the adhesive frame 20, thereby increasing the service life of the first functional layer 13. In a case where the material of the adhesive frame 20 includes PVB, the material of the adhesive frame 20 exhibits fluidity during the laminating process. The deformation gap 1 may provide a flow space for the adhesive frame 20, reducing the risk of the adhesive frame 20 flowing to a surface of the first functional layer 13 away from the first substrate 11. For example, the deformation gap 1 ranges from 1 mm to 5 mm, such as 1 mm, 2.5 mm, or 5 mm, enabling the first functional layer 13 not to be compressed against the adhesive frame 20 during thermal expansion and contraction.

The adhesive frame 20 may include a plurality of adhesive layers disposed in stack, that is, a thickness of the adhesive frame is N×d, where N is the number of the adhesive layers, and the number of the adhesive layers is less than six. For example, the number of the adhesive layers ranges from two to five, that is, N ranges from 2 to 5. For example, the number of the adhesive layers is one, four or five, which is not enumerated one by one in the embodiments of the present disclosure. The thickness of the adhesive layer ranges from 0.3 mm to 0.5 mm. For example, the thickness of the adhesive layer is 0.3 mm, 0.35 mm, 0.38 mm, 0.4 mm, 0.45 mm, 0.48 mm, or 0.5 mm, which is not enumerated one by one in the embodiments of the present disclosure. Here, the thickness of the adhesive frame 20 refers to a distance between a surface of the adhesive frame 20 away from the first substrate 11 and a surface of the first substrate 11 proximate to the adhesive frame 20.

As shown in FIG. 3, in S300, a second stacked structure 40 is attached to a side of the adhesive frame 20 away from the first substrate 11.

In some embodiments, as shown in FIG. 3, the second stacked structure 40 is located on a side of the first functional layer 13 away from the first substrate 11, and has a first gap 2 from the first stacked structure 10. The first gap 2 communicates with the first opening 21. The adhesive frame 20 is bonded to the second stacked structure 40.

A thickness of the first gap 2 is N×d₂-M×d₁-d₃. For example, the thickness of the first gap 2 ranges from 0.1 mm to 1 mm. For example, the thickness of the first gap 2 is 0.1 mm, 0.38 mm, 0.5 mm, 0.78 mm, or 1 mm, which is not enumerated one by one in the embodiments of the present disclosure.

As shown in FIG. 4, in S400, the first stacked structure 10, the adhesive frame 20 and the second stacked structure 40 are laminated.

The first adhesive layer 12 bonds the first substrate 11 and the first functional layer 13, and the adhesive frame 20 bonds the first stacked structure 10 and the second stacked structure 40. The adhesive frame 20 abuts against the first functional layer 13.

A material of the adhesive frame 20 includes PVB, and the process conditions of laminating are high temperature and high pressure. For example, the first stacked structure 10, the adhesive frame 20 and the second stacked structure 40 are laminated in an autoclave.

Under the conditions of high temperature and high pressure, the material of the adhesive layer exhibits fluidity, so the thickness d of the adhesive frame 20 may remain unchanged or decrease. That is, the thickness of the first adhesive layer 12 changes from M×d to M×d₁, and the thickness of the adhesive frame 20 changes from N×d to N×d₂, where d₁ is less than or equal to d, d₂ is less than or equal to d, and d₁ and d₂ range from 0.3 mm to 0.5 mm. For example, d₁ is 0.3 mm, 0.35 mm, 0.38 mm, 0.4 mm, 0.45 mm, 0.48 mm, or 0.5 mm, and d₂ is 0.3 mm, 0.35 mm, 0.38 mm, 0.4 mm, 0.45 mm, 0.48 mm, or 0.5 mm, which is not enumerated one by one in the embodiments of the present disclosure.

Since the thickness of the adhesive frame 20 is greater than the thickness of the first adhesive layer 12, the fluidity of the material of the adhesive layer included in the adhesive frame 20 is less than or equal to the fluidity of the material of the adhesive layer included in the first adhesive layer 12. That is, the reduction value of the thickness of the adhesive layer included in the adhesive frame 20 is less than or equal to the reduction value of the adhesive layer included in the first adhesive layer 12. In other words, the thickness d₂ of the adhesive layer included in the adhesive frame 20 is greater than or equal to the thickness d₁ of the adhesive layer included in the first adhesive layer 12.

For example, the thickness d₂ of the adhesive layer included in the adhesive frame 20 is equal to the thickness d₁ of the adhesive layer included in the first adhesive layer 12, that is, d₁ and d₂ are both 0.3 mm, 0.35 mm, 0.38 mm, 0.4 mm, 0.45 mm, 0.48 mm, or 0.5 mm, which is not enumerated one by one in the embodiments of the present disclosure.

Alternatively, for example, the thickness d₂ of the adhesive layer included in the adhesive frame 20 is greater than the thickness d₁ of the adhesive layer included in the first adhesive layer 12. For example, d₂ is 0.38 mm and d₁ is 0.35 mm, or d₂ is 0.4 mm and d₁ is 0.35 mm, or d₂ is 0.48 mm and d₁ is 0.4 mm, or d₂ is 0.5 mm and d₁ is 0.48 mm, which is not enumerated one by one in the embodiments of the present disclosure.

In a case where the thickness of the first adhesive layer 12 is inconsistent, a thicker portion of the first adhesive layer 12 arches in a direction from the first substrate 11 toward the second stacked structure 40, and accordingly, a portion of the first functional layer 13 bonded to that portion arches in the direction from the first substrate 11 toward the second stacked structure 40. A thinner portion of the first adhesive layer 12 concaves in a direction from the second stacked structure 40 toward the first substrate 11, and accordingly, a portion of the first functional layer 13 bonded to that portion moves in the direction from the second stacked structure 40 toward the first substrate 11. In this way, the stress applied by the first adhesive layer 12 on the first functional layer 13 is released, which may reduce the risk of uneven force on the first functional layer 13 due to the inconsistent thickness of the first adhesive layer 12.

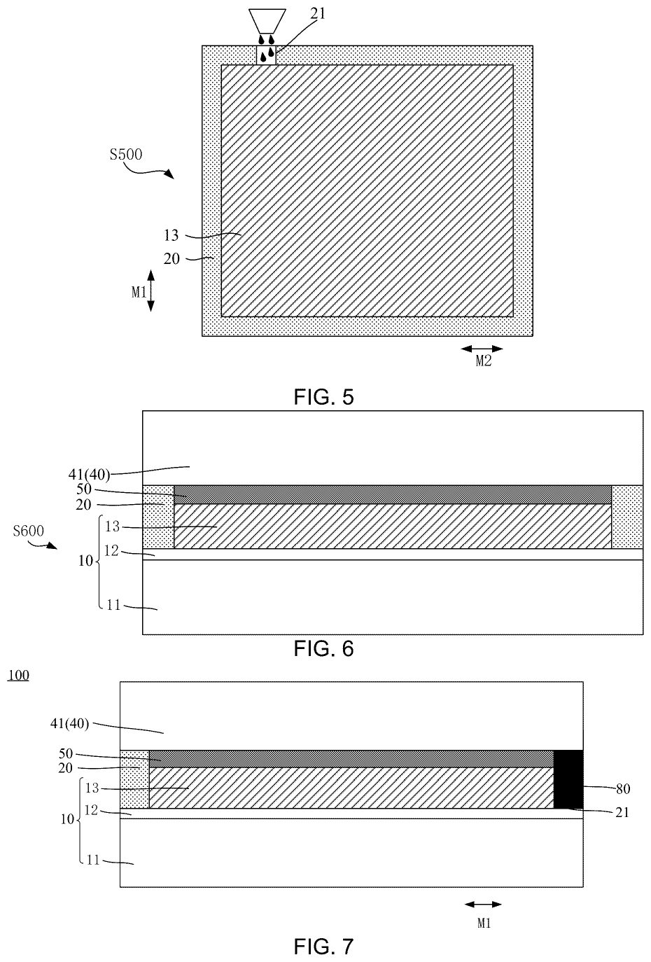

As shown in FIG. 5, in S500, a liquid adhesive is injected into the first gap 2 through the at least one first opening of the adhesive frame 20.

The liquid adhesive may be an adhesive with relatively high light transmittance, for example, the liquid adhesive may be an optical clear resin (OCR) or an ultraviolet (UV) adhesive.

As shown in FIG. 6, in S600, the liquid adhesive is solidified to form a second adhesive layer 50.

The second adhesive layer 50 bonds the first stacked structure 10 and the second stacked structure 40. The second adhesive layer 50 is formed by an adhesive pouring and a solidifying process. The second adhesive layer 50 has no force or a small force on the first functional layer 13.

A cell thickness (a distance between the first substrate 11 and the second substrate 41) of the dimming device 100 formed according to the above steps is highly consistent. For example, the change in the cell thickness of the dimming device 100 is less than or equal to 0.1 mm.

A thickness of the second adhesive layer 50 is equal to the thickness of the first gap 2, that is, the thickness of the second adhesive layer 50 is N×d₂-M×d₁-d₃. For example, the thickness of the second adhesive layer 50 ranges from 0.1 mm to 1 mm. For example, the thickness of the second adhesive layer 50 may be 0.1 mm, 0.38 mm, 0.5 mm, 0.78 mm, or 1 mm, which is not enumerated one by one in the embodiments of the present disclosure.

The embodiments of the present disclosure further provide a dimming device 100. As shown in FIG. 7, the dimming device 100 includes a first stacked structure 10, a second stacked structure 40, a second adhesive layer 50, an adhesive frame 20, and sealing block(s) 80.

As shown in FIG. 7, the first stacked structure 10 includes a first substrate 11, a first adhesive layer 12 and a first functional layer 13 disposed in stack. A material of the first substrate 11 may include a material with high light transmittance (such as light transmittance greater than 85%). For example, the material of the first substrate 11 is tempered glass.

A material of the first adhesive layer 12 may include optically clear adhesive (OCA), PVB, ethylene vinyl acetate (EVA), sentry glass plus (SGP), optical clear resin (OCR), or any of other adhesive materials with high light transmittance. For example, the material of the first adhesive layer 12 includes PVB.

In some embodiments, the first adhesive layer 12 may include a plurality of adhesive layers disposed in stack, and the number of the adhesive layers is less than six. For example, the number of the adhesive layers ranges from one to three, which is not enumerated one by one in the embodiments of the present disclosure. The thickness of the adhesive layer ranges from 0.3 mm to 0.5 mm. For example, the thickness of the adhesive layer is 0.3 mm, 0.35 mm, 0.38 mm, 0.4 mm, 0.45 mm, 0.48 mm, or 0.5 mm, which is not enumerated one by one in the embodiments of the present disclosure.

During manufacturing the dimming device 100, the first adhesive layer 12 needs to undergo a high-temperature and high-pressure laminating process. Under the conditions of high temperature and high pressure, the material of the adhesive layer exhibits fluidity, enabling the thickness of the adhesive layer after high temperature and high pressure to be less than or equal to the thickness of the adhesive layer before high temperature and high pressure. That is to say, the thickness of the first adhesive layer 12 before high temperature and high pressure is M×d, where M is the number of the adhesive layers and d is the thickness of the adhesive layer; and the thickness of the first adhesive layer 12 after high temperature and high pressure is M×d₁, where d₁ is less than or equal to d, and d₁ ranges from 0.3 mm to 0.5 mm. For example, d₁ is 0.3 mm, 0.35 mm, 0.38 mm, 0.4 mm, 0.45 mm, 0.48 mm, or 0.5 mm, which is not enumerated one by one in the embodiments of the present disclosure.

The thickness of the first adhesive layer 12 may be designed according to the thickness of the dimming device 100. For example, if the thickness of the dimming device 100 is less than or equal to 5 mm, the thickness of the first adhesive layer 12 ranges from 0.3 mm to 0.35 mm, for example, the thickness of the first adhesive layer 12 is 0.3 mm, 0.33 mm or 0.35 mm.

The thickness of the first functional layer is d₃, where d₃ is less than or equal to 1.1 mm. For example, d₃ is 1.1 mm, 1 mm, 0.78 mm, 0.38 mm, or 0.15 mm, which is not enumerated one by one in the embodiments of the present disclosure.

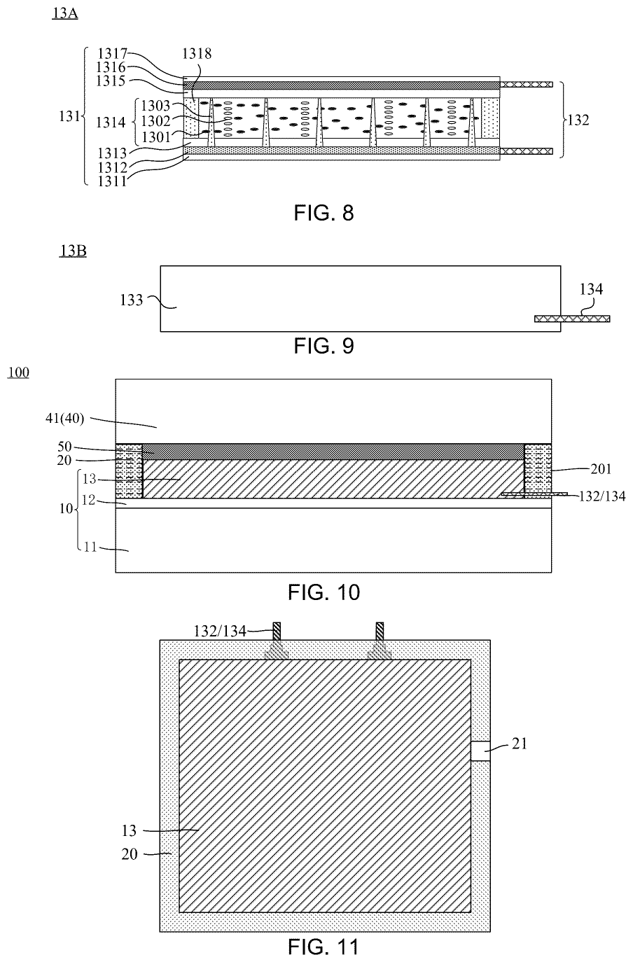

FIG. 8 is a structural diagram of the first functional layer 13 that is a dimming functional layer. In some embodiments, as shown in FIG. 8, the first functional layer 13 is a dimming functional layer 13A, and the dimming functional layer 13A is used to adjust light transmittance. In this case, the material of the first adhesive layer is PVB or SGP. The first adhesive layer 12 has good adhesion, which may enhance the firmness of the first functional layer 13 and the first substrate 11.

The dimming functional layer 13A is a polymer dispersed liquid crystal (PDLC) functional layer, an electrochromic (EC) functional layer, a dye liquid crystal functional layer, or a suspended particle (SP) functional layer. The embodiments of the present disclosure are described by taking the dimming functional layer 13A being a dye liquid crystal functional layer as an example.

As shown in FIG. 8, the dimming functional layer 13A includes a dye liquid crystal panel 131 and a first flexible circuit board 132. The dye liquid crystal panel 131 is used to adjust light transmittance, and the first flexible circuit board 132 is used to drive the dye liquid crystal panel 131 to adjust light transmittance.

The dye liquid crystal panel 131 includes a first base material layer 1311, a first electrode layer 1312, a first alignment layer 1313, a dye liquid crystal layer 1314, a second alignment layer 1315, a second electrode layer 1316, and a second base material layer 1317 stacked in sequence; and the dye liquid crystal panel 131 further includes a sealant 1318. Materials of the first base material layer 1311 and the second base material layer 1317 may include glass or plastic. The plastic may include polyethylene terephthalate (PET), polyethylene naphthalate (PEN), polycarbonate (PC), polyphenylene sulfone resins (PPSU), cyclo olefin polymer (COP), or polymethyl methacrylate (PMMA).

Materials of the first electrode layer 1312 and the second electrode layer 1316 include a conductive material with high light transmittance. For example, the materials of the first electrode layer 1312 and the second electrode layer 1316 include indium tin oxide (ITO).

The dye liquid crystal layer 1314 includes dye molecules 1301 and liquid crystal molecules 1302 (in FIG. 8, black ellipses represent the dye molecules and white ellipses represent the liquid crystal molecules). As an angle formed between a long axis direction of the dye molecule 1301 and a direction of an electric field between the first electrode layer 1312 and the second electrode layer 1316 varies, the amount of light absorbed by the dye molecule 1301 also differs. By changing the voltage value between the first electrode layer 1312 and the second electrode layer 1316, an angle formed by a long axis direction of the liquid crystal molecule 1302 and a direction of an electric field between the first electrode layer 1312 and the second electrode layer 1316 may be changed, which may lead to a change in the angle formed between the long axis direction of the dye molecule 1301 and the direction of the electric field between the first electrode layer 1312 and the second electrode layer 1316. Consequently, the amount of light absorbed by the dye molecule 1301 is changed, thereby adjusting the light transmittance of the dye liquid crystal layer 1314. For example, in a case where the long axis direction of the dye molecule 1301 is parallel to the direction of the electric field between the first electrode layer 1312 and the second electrode layer 1316, light can pass through the dye liquid crystal layer 1314, thereby making the dye liquid crystal functional layer transparent (in a bright state). For another example, in a case where the long axis direction of the dye molecule 1301 is perpendicular to the direction of the electric field between the first electrode layer 1312 and the second electrode layer 1316, light cannot pass through the dye liquid crystal layer 1314, thereby making the dye liquid crystal functional layer be in a dark state.

The dye liquid crystal layer 1314 further includes a plurality of spacers 1303, and the plurality of spacers 1303 are arranged at intervals. The spacers 1303 are located between the second alignment layer 1315 and the first electrode layer 1312, and penetrate the first alignment layer 1313. The plurality of spacers 1303 is used to maintain a distance between the first base material layer 1311 and the second base material layer 1317.

FIG. 9 is a structural diagram of the first functional layer 13 that is a display functional layer 13B. In some other embodiments, as shown in FIG. 9, the first functional layer 13 may also be a display functional layer 13B. The display functional layer 13B has a high light transmittance and is used to display images. For example, the display functional layer 13B is an organic light-emitting diode (OLED) display functional layer, a quantum dot light-emitting diode (QLED) display functional layer, an active-matrix organic light-emitting diode (AMOLED) display functional layer, a micro light-emitting diode (Micro LED) display functional layer, or a sub-millimeter light-emitting diode (Mini LED) display functional layer. Here, Micro LED refers to LED chips less than 50 μm in size, while Mini LED refers to LED chips ranging from 50 μm to 200 μm in size. For example, the display functional layer 13B is an OLED display functional layer. The display functional layer 13B includes a display panel 133 and a second flexible circuit board 134, in which the second flexible circuit board 134 is electrically connected to the display panel 133, and the second flexible circuit board 134 is used to drive the display panel 133 to display images.

As shown in FIG. 7, the second stacked structure 40 is located on a side of the first substrate 11 proximate to the first adhesive layer 12. The second stacked structure 40 includes a second substrate 41. The second substrate 41 and the first substrate 11 may be made of a same material. For example, the material of the first substrate 11 and the second substrate 41 may include tempered glass.

The second adhesive layer 50 is located between the first stacked structure 10 and the second stacked structure 40, and is used to bond the first stacked structure 10 and the second stacked structure 40.

A thickness of the second adhesive layer 50 is N×d₂-M×d₁-d₃. For example, the thickness of the second adhesive layer 50 may be designed according to the thickness of the dimming device 100. For example, if the thickness of the dimming device 100 is less than or equal to 5 mm, the thickness of the second adhesive layer 50 is in a range of 0.1 mm to 1 mm. For example, the thickness of the second adhesive layer 50 is 1.1 mm, 1 mm, 0.78 mm, 0.38 mm, or 0.15 mm, which is not enumerated one by one in the embodiments of the present disclosure.

The adhesive frame 20 is located between the first substrate 11 and the second substrate 41, and the adhesive frame 20 surrounds the first functional layer 13 and the second adhesive layer 50. In this way, the adhesive frame 20 may prevent external water vapor from entering the first functional layer 13 and the second adhesive layer 50, thereby reducing the risk of water vapor corroding the first functional layer 13 and the second adhesive layer 50, so as to increase the service life of the dimming device 100. The adhesive frame 20 is located on a side of the first substrate 11 proximate to the first functional layer 13 and surrounds the first functional layer 13. The adhesive frame may block the passage of water vapor in the air. In this way, the adhesive frame 20 may alleviate the problem of water vapor in the atmosphere entering the first functional layer 13, reduce the risk of material aging in the first functional layer 13, and increase the service life of the first functional layer 13. For example, a width of the adhesive frame 20 may range from 5 mm to 50 mm. For example, the width of the adhesive frame 20 is 5 mm, 25 mm, or 50 mm, which may ensure that the adhesive frame blocks water vapor.

The material of the adhesive frame 20 includes PVB, EVA, or SGP, which is not enumerated one by one in the embodiments of the present disclosure. As shown in FIG. 10, the adhesive frame 20 may include a plurality of adhesive layers 201 disposed in stack, and the number of the adhesive layers is less than six. For example, the number of the adhesive layers ranges from two to five. The thickness of the adhesive layer ranges from 0.3 mm to 0.5 mm. For example, the thickness of the adhesive layer is 0.3 mm, 0.35 mm, 0.38 mm, 0.4 mm, 0.45 mm, 0.48 mm, or 0.5 mm, which is not enumerated one by one in the embodiments of the present disclosure. That is to say, the thickness of the adhesive frame 20 is a multiple of the specification of the adhesive layer.

During manufacturing the dimming device 100, the adhesive frame 20 needs to undergo a high-temperature and high-pressure laminating process. Under the conditions of high temperature and high pressure, the material of the adhesive layer exhibits fluidity, enabling the thickness of the adhesive layer after high temperature and high pressure to be less than or equal to the thickness of the adhesive layer before high temperature and high pressure. That is to say, the thickness of the adhesive frame before high temperature and high pressure is N×d, where N is the number of the adhesive layers and d is the thickness of the adhesive layer; and the thickness of the adhesive frame after high temperature and high pressure is N×d₂, where d₂ is less than or equal to d, and d₂ ranges from 0.3 mm to 0.5 mm. For example, d₂ is 0.3 mm, 0.35 mm, 0.38 mm, 0.4 mm, 0.45 mm, 0.48 mm, or 0.5 mm, which is not enumerated one by one in the embodiments of the present disclosure.

Since the thickness of the adhesive frame 20 is greater than the thickness of the first adhesive layer 12, the fluidity of the material of the adhesive layer included in the adhesive frame 20 is less than or equal to the fluidity of the material of the adhesive layer included in the first adhesive layer 12. That is, the reduction value of the thickness of the adhesive layer included in the adhesive frame 20 is less than or equal to the reduction value of the adhesive layer included in the first adhesive layer 12. In other words, the thickness d₂ of the adhesive layer included in the adhesive frame 20 is greater than or equal to the thickness d₁ of the adhesive layer included in the first adhesive layer 12.

For example, the thickness d₂ of the adhesive layer included in the adhesive frame 20 is equal to the thickness d₁ of the adhesive layer included in the first adhesive layer 12, that is, d₁ and d₂ are both 0.3 mm, 0.35 mm, 0.38 mm, 0.4 mm, 0.45 mm, 0.48 mm, or 0.5 mm, which is not enumerated one by one in the embodiments of the present disclosure. Alternatively, for example, the thickness d₂ of the adhesive layer included in the adhesive frame 20 is greater than the thickness d₁ of the adhesive layer included in the first adhesive layer 12. For example, d₂ is 0.38 mm and d₁ is 0.35 mm, or d₂ is 0.4 mm and d₁ is 0.35 mm, or d₂ is 0.48 mm and d₁ is 0.4 mm, or d₂ is 0.5 mm and d₁ is 0.48 mm, which is not enumerated one by one in the embodiments of the present disclosure.

In some embodiments, the thickness of the first adhesive layer 12 is 0.38 mm, the thickness of the second adhesive layer 50 is 0.38 mm, the thickness of the first functional layer 13 is 0.38 mm, and the thickness of the adhesive frame is 1.14 mm. In some other embodiments, the thickness of the first adhesive layer 12 is 0.76 mm, the thickness of the second adhesive layer 50 is 0.38 mm, the thickness of the first functional layer 13 is 0.76 mm, and the thickness of the adhesive frame is 1.9 mm.

Based on the above structure, the thickness of the adhesive frame 20 may be changed by changing the number of the adhesive layers 201, which is more convenient. In a case where the first functional layer 13 includes a flexible circuit board (the first flexible circuit board 132 or the second flexible circuit board 134), the flexible circuit board 132/134 may extend straight outward and extend between two adjacent adhesive layers 201, so that the flexible circuit board 132/134 does not need to be bent. Compared with a situation where the flexible circuit board 132/134 needs to be bent around an adhesive frame 20 to extend out when using the solid-piece adhesive frame 20, the scheme where the adhesive frame 20 is formed by a plurality of adhesive layers 201 may reduce the risk of damage to the flexible circuit board 132/134 caused by bending.

For example, the material of the adhesive frame is a PVB sheet. When the PVB sheet is not bonded to a substrate or a film layer, a surface of the PVB sheet is rough, that is, the surface of the PVB sheet is uneven. On this basis, in a case where the second stacked structure 40 includes the second substrate 41, the adhesive frame 20 is in contact with the second substrate 41. Since a surface of the adhesive frame 20 formed by the PVB sheet is uneven, there is a small gap between the adhesive frame 20 and the second substrate 41. In the subsequent manufacturing process, the air in the deformation gap 1 between the adhesive frame 20 and the first functional layer 13 may be discharged through the small gap between the adhesive frame 20 and the second substrate 41, thereby avoiding the generation of bubbles in the dimming device 100.

As shown in FIG. 5 and FIG. 7, the adhesive frame 20 has at least one first opening 21. A projection of the first opening 21 along a first direction M1 at least partially overlaps with an orthographic projection of the second adhesive layer 50 along the first direction M1. Thus, before S500 (injecting liquid adhesive into the first gap 2 through the at least one first opening of the adhesive frame 20), the first opening 21 communicates with the first gap 2, so that the liquid adhesive may be injected into the dimming device 100 through the first opening 21, and then the liquid adhesive is solidified to form the above-mentioned second adhesive layer 50. That is, the second adhesive layer 50 is formed through an adhesive filling and a solidifying process, and the second adhesive layer 50 has no force or a small force on the first functional layer 13, which may increase the service life of the first functional layer 13. Here, the first direction M1 is perpendicular to a side surface where the first opening 21 is located.

As shown in FIG. 5 and FIG. 7, along a second direction M2, a dimension of the first opening 21 is less than or equal to half a dimension of the first substrate 11. For example, the dimension of the first opening 21 is less than or equal to half, one third or one-quarter of the dimension of the first substrate 11. That is, along the second direction M2, the dimension of the first opening 21 is less than a dimension of the side surface of the adhesive frame 20 where the first opening 21 is located. Here, the first direction M1 is substantially parallel to the side surface where the first opening 21 is located.

For example, the adhesive frame 20 has one first opening 21, two first openings 21, or three first openings 21. For example, the adhesive frame 20 has one first opening 21, so that less portion of the adhesive frame 20 is removed, thereby reducing the risk of poor sealing of the adhesive frame 20. For another example, the adhesive frame 20 has three first openings 21, which may increase the speed of adhesive filling and reduce the manufacturing time of the dimming device 100.

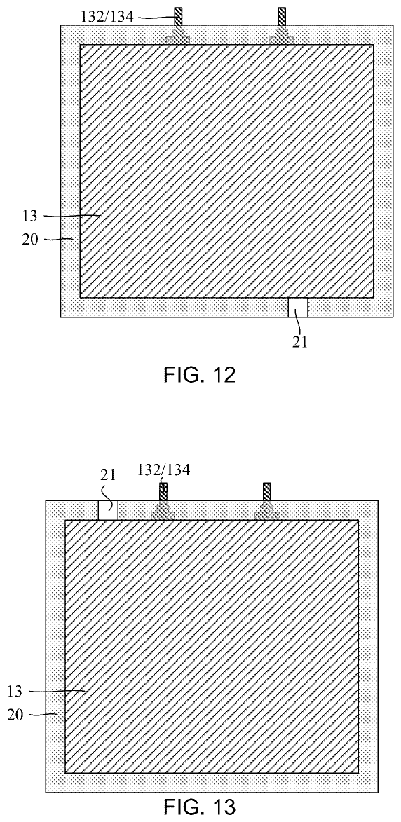

FIG. 11 to FIG. 13 are several schematic diagrams showing the positional relationship between the first opening 21 and the flexible printed circuit board 132/134. For example, as shown in FIG. 11, the first opening 21 and the flexible circuit board are located on adjacent sides of the adhesive frame 20. For example, the flexible circuit board is located on the upper side of the adhesive frame 20, and the first opening 21 is located on the left side or right side of the adhesive frame 20. Alternatively, for example, as shown in FIG. 12, the first opening 21 and the flexible circuit board are located on opposite sides of the adhesive frame 20. Alternatively, for example, as shown in FIG. 13, the first opening 21 and the flexible circuit board are located on the same side of the adhesive frame 20. In a case where the dimming device 100 is applied to vehicle window glass, the flexible circuit board is located on the lower side. In this way, when the vehicle window glass is raised or lowered, the flexible circuit board is hidden in the vehicle door. The first opening 21 and the flexible circuit board are located on the same side of the adhesive frame 20. Therefore, the first opening 21 is also hidden in the vehicle door. Since a sealing block 80 is provided to seal the first opening 21 after the adhesive filling is completed, the sealing block 80 may also be hidden in the vehicle door using the above design, so that the sealing block 80 is not easily damaged, thereby reducing the risk of water vapor entering the interior of the dimming device 100 through the first opening 21.

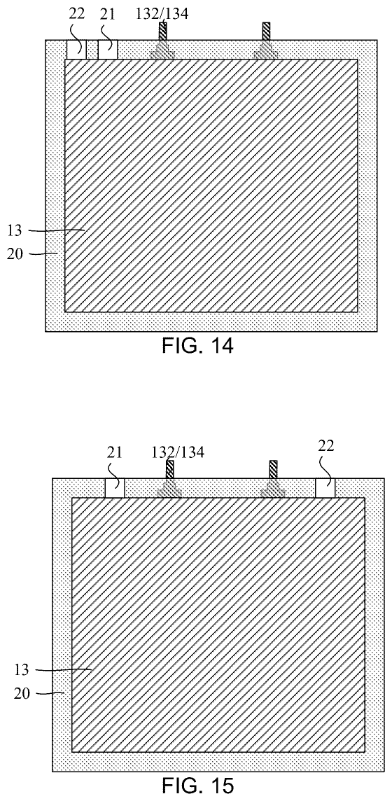

In some embodiments, as shown in FIG. 14, the adhesive frame 20 further has at least one second opening 22. During the process of injecting the liquid adhesive into the first gap, the second opening 22 may discharge air in the first gap, thereby reducing the risk of bubbles in the dimming device 100. For example, the adhesive frame 20 further has one second opening 22, two second openings 22 or three second openings 22, which may ensure normal exhaust of the dimming device 100. The first opening 21 and the second opening 22 are located on the same side of the adhesive frame 20.

In a case where the first opening 21 and the flexible circuit board are located on the same side of the adhesive frame 20, the relative position of the first opening 21, the second opening 22 and the flexible circuit board may be set according to actual conditions. For example, as shown in FIG. 14, the first opening 21 and the second opening 22 are located on the same side of the flexible circuit board. For another example, as shown in FIG. 15, the first opening 21 is located on one side of the flexible circuit board, and the second opening 22 is located on the other side of the flexible circuit board. In a case where the adhesive frame 20 is formed by stacking a plurality of adhesive layers, the flexible circuit board 132/134 extends from between two adjacent adhesive layers, and there is a certain distance between the flexible circuit board 132/134 and the first opening 21 to ensure that a portion of the flexible circuit board 132/134 located within the adhesive frame 20 is completely wrapped by the adhesive frame 20, and the plurality of adhesive layers at the first opening 21 are not separated by the flexible circuit board 132/134, thereby ensuring good sealing performance of the adhesive frame 20. For example, a distance between the first opening 21 and the flexible circuit board is greater than 30 mm.

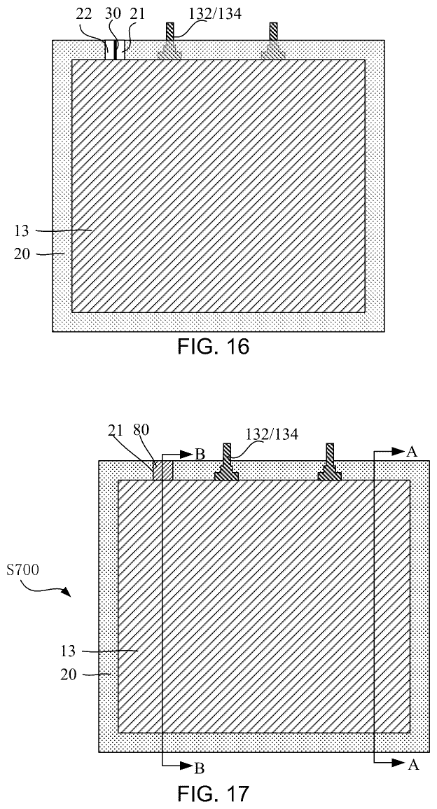

In some embodiments, as shown in FIG. 16, a baffle 30 is used in the process of forming the first opening 21 and the second opening 22. The adhesive frame 20 has one opening, and the baffle 30 is located within the opening, dividing the opening into two sub-openings, one of which is the first opening 21 and the other is the second opening 22. The adhesive frame 20 has one opening, so that less portion of the adhesive frame 20 is removed, thereby reducing the risk of poor sealing of the adhesive frame 20.

As shown in FIG. 7, the sealing block 80 is located at the first opening 21 and seals the first opening 21. The sealing block 80 may reduce the risk of water vapor entering the second adhesive layer 50 through the first opening 21. For example, the material of the sealing block 80 is hot-melt butyl adhesive.

On the basis of the above embodiments, after S600 (solidifying the liquid adhesive to form the second adhesive layer 50), the manufacturing method further includes a step (S700).

As shown in FIG. 17, in S700, the first opening 21 is sealed.

Hot-melt butyl adhesive is applied in the first opening 21 to seal the first opening 21. The hot-melt butyl adhesive may reduce the risk of water vapor in the air entering the second adhesive layer.

In a case where the dimming device 100 includes the baffle 30 (as shown in FIG. 16), the baffle 30 needs to be removed from the first opening 21 before the first opening 21 is sealed.

In some embodiments, as shown in FIG. 7, the material of the adhesive frame 20 and the material of the sealing block 80 are different. For example, the material of the adhesive frame 20 is PVB, and the material of the sealing block 80 is hot-melt butyl adhesive.

The material of the adhesive frame 20 is the same as the material of the first adhesive layer 12, which may improve the material uniformity of the dimming device 100 and reduce the manufacturing cost of the dimming device 100. During the process of forming the dimming device 100, the material of the adhesive frame 20 will penetrate into the first adhesive layer 12, and the material of the first adhesive layer 12 will penetrate into the adhesive frame 20, so that the first adhesive layer 12 and the adhesive frame 20 become a whole, thereby making the adhesive frame 20 and the first substrate 11 more firmly bonded.

The material of the first adhesive layer 12 is different from the material of the second adhesive layer 50. The material of the first adhesive layer 12 has good impact resistance, which may reduce the risk of the first substrate 11 being broken due to external impact of a certain energy or temperature changes. The material of the second adhesive layer 50 has good stress absorption performance and can absorb the stress applied by the first functional layer 13 on the second adhesive layer 50, i.e., can absorb the stress applied on the first functional layer 13 due to the uneven thickness of the first adhesive layer 12. In this way, the stress applied by the second adhesive layer 50 on the first functional layer 13 is small or non-existent, which may reduce the risk of uneven force on the first functional layer 13.

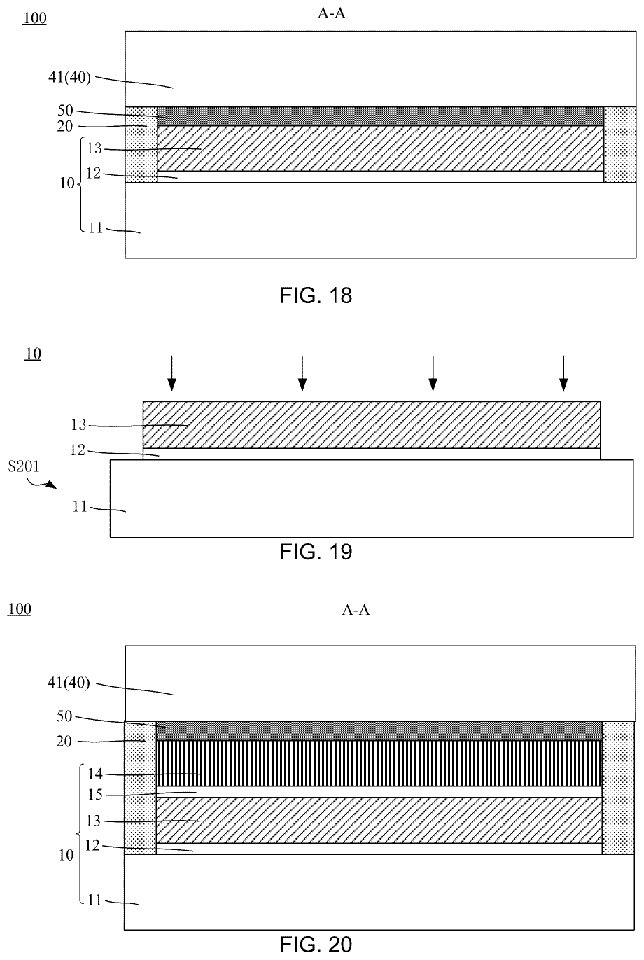

In some embodiments, the material of the adhesive frame is a PVB sheet. In a case where the PVB sheet is not bonded to a substrate or a film layer, a surface of the PVB sheet is rough, that is, the surface of the PVB sheet is uneven. On this basis, as shown in FIG. 18, an orthographic projection of the first adhesive layer 12 on a reference surface is located within an orthographic projection of the first substrate 11 on the reference surface, and has a spacing from a boundary of the orthographic projection of the first substrate 11; and the orthographic projection of the first adhesive layer 12 on the reference surface coincides with an orthographic projection of the first functional layer 13 on the reference surface. The reference surface is parallel to a surface of the first substrate 11 proximate to the first functional layer 13.

In this way, after S200 (forming the adhesive frame 20 on a side of the first stacked structure 10), the adhesive frame 20 abuts against the first substrate 11. Since a surface of the adhesive frame 20 formed by the PVB sheet is uneven, there is a small gap between the adhesive frame 20 and the first substrate 11. In the subsequent manufacturing process, the air in the deformation gap 1 between the adhesive frame 20 and the first functional layer 13 may be discharged through the small gap between the adhesive frame 20 and the first substrate 11, thereby avoiding the generation of bubbles in the dimming device 100.

In the above embodiments, during the subsequent bonding of the second stacked structure, the thickness of the adhesive frame 20 is greater than the sum of the thickness of the first adhesive layer 12 and the thickness of the first functional layer 13, thereby allowing the second stacked structure and the first functional layer 13 to have the first gap therebetween.

On the basis of the above embodiments, between S100 (forming the first stacked structure 10) and S200 (forming the adhesive frame 20 on a side of the first stacked structure 10), the manufacturing method further includes steps (S201 to S202).

As shown in FIG. 19, in S201, pressure is applied to the first stacked structure 10.

In some embodiments, the material of the first adhesive layer is a PVB sheet. In a case where the PVB sheet is not bonded to a substrate or film layer, a surface of the PVB sheet is rough, that is, the surface of the PVB sheet is uneven. In this way, there is a small gap between the first adhesive layer 12 and the first substrate 11 in the first stacked structure 10, and the small gap can accommodate air. Applying pressure to the first stacked structure 10 can remove the air in the small gap between the first adhesive layer 12 and the first substrate 11, thereby increasing the bonding area of the first adhesive layer 12 and the first substrate 11 and making the connection between the first adhesive layer 12 and the first substrate 11 more secure.

In S202, the first stacked structure 10 is laminated.

The first adhesive layer 12 bonds the first substrate 11 and the first functional layer 13 together. For example, the material of the first adhesive layer 12 is PVB, and the process conditions for laminating the first stacked structure 10 are high temperature and high pressure. Alternatively, for example, the material of the first adhesive layer 12 is EVA, a temperature for laminating the first stacked structure 10 is lower than a temperature for laminating PVB, and pressure for laminating the first stacked structure 10 is lower than pressure for laminating PVB. In this way, the laminating process of EVA is relatively simple, which may reduce the manufacturing cost of the first stacked structure 10. Alternatively, for example, the material of the first adhesive layer 12 is SGP, the strength of SGP is higher than the strength of PVB, and the shear modulus of SGP is higher than the shear modulus of PVB. In a case where the first adhesive layer 12 has the fixed thickness, the strength of the first adhesive layer 12 composed of SGP is higher than the strength of the first adhesive layer 12 composed of PVB, thereby improving the strength of the first stacked structure 10.

As shown in FIG. 18, the orthographic projection of the first functional layer 13 on the reference surface coincides with the orthographic projection of the first adhesive layer 12 on the reference surface. Compared to a situation where the orthographic projection of the first functional layer 13 is located within the orthographic projection of the first adhesive layer 12 on the reference surface and has a spacing from a boundary of the orthographic projection of the first adhesive layer 12, during the process of applying pressure to the first stacked structure 10 and laminating the first stacked structure 10, the entire first adhesive layer 12 of some embodiments of the present disclosure is compressed, which enables the thickness of the first adhesive layer 12 to be consistent, so that the first functional layer 13 may be subjected to more uniform force.

In some other embodiments, as shown in FIG. 7, an orthographic projection of the first adhesive layer 12 on the reference surface coincides with an orthographic projection of the first substrate 11 on the reference surface, and an orthographic projection of the first functional layer 13 on the reference surface is located within the orthographic projection of the first adhesive layer 12 on the reference surface, and has a spacing from a boundary of the orthographic projection of the first adhesive layer 12. In this way, the first adhesive layer 12 covers the first substrate 11. If the first substrate 11 is broken by an external impact of a certain energy or temperature changes, any portion of the first substrate 11 will stick to the first adhesive layer 12, reducing the risk of fragments of the first substrate 11 flying around.

The thickness of the adhesive frame 20 is greater than the thickness of the first functional layer 13, so that in the subsequent process of laminating the second stacked structure, the second stacked structure and the first functional layer 13 have the first gap therebetween.

FIG. 20 is a structural diagram of the first stacked structure 10 further including a second functional layer 14. In some embodiments, as shown in FIG. 20, the first stacked structure 10 further includes a second functional layer 14 and a third adhesive layer 15, in which the second functional layer 14 is located on a side of the first functional layer 13 away from the first substrate 11, and the third adhesive layer 15 is located between the first functional layer 13 and the second functional layer 14, and is used to bond the first functional layer 13 and the second functional layer 14. After S200 (forming the adhesive frame 20 on a side of the first stacked structure 10), an end of the adhesive frame 20 away from the first substrate 11 is farther away from the first substrate 11 than an end of the second functional layer 14 away from the first substrate 11. That is, along the thickness direction of the first stacked structure 10, the upper surface of the adhesive frame 20 is higher than the upper surface of the second functional layer 14.

The types of the first functional layer 13 and the second functional layer 14 may be set according to actual conditions. For example, the first functional layer 13 is a dye liquid crystal functional layer, and the second functional layer 14 is also a dye liquid crystal functional layer. The first functional layer 13 may have a light transmittance different from that of the second functional layer 14. The first functional layer 13 and the second functional layer 14 cooperate to enable the dimming device 100 to have at least two regions with different light transmittances. Alternatively, the first functional layer 13 and the second functional layer 14 cooperate to reduce the dark-state transmittance of the dimming device.

Alternatively, for example, the first functional layer 13 is a dye liquid crystal functional layer, and the second functional layer 14 is a touch functional layer. The touch functional layer is electrically connected to the dye liquid crystal functional layer, so that the light transmittance of the dye liquid crystal functional layer may be adjusted through the touch functional layer, which is convenient for operation. For example, it is possible to adjust the light transmittance by swiping fingers.

Alternatively, for example, the first functional layer 13 is a display functional layer, and the second functional layer 14 is a dye liquid crystal functional layer. Alternatively, the first functional layer 13 is a display functional layer, and the second functional layer 14 is a touch functional layer.

The third adhesive layer 15 is used to connect the first functional layer 13 and the second functional layer 14. A material of the third adhesive layer 15 may be the same as the material of the first adhesive layer 12. For example, the materials of the third adhesive layer 15 and the first adhesive layer 12 are both PVB.

Based on the above embodiments, as shown in FIG. 4, in the process of S400 (laminating the first stacked structure 10, the adhesive frame 20 and the second stacked structure 40), the first gap 2 provides a moving space for the first functional layer 13 and the second functional layer 14. In a case where the thickness of the first adhesive layer 12 is inconsistent, a thicker portion of the first adhesive layer 12 arches in a direction from the first substrate 11 toward the second substrate 41, and accordingly, a portion of the first functional layer 13 bonded to that portion arches in the direction from the first substrate 11 toward the second substrate 41, and a corresponding portion of the second functional layer 14 arches in the direction from the first substrate 11 toward the second substrate 41; and a thinner portion of the first adhesive layer 12 concaves in a direction from the second substrate 41 toward the first substrate 11, and accordingly, a portion of the first functional layer 13 bonded to that portion concaves in the direction from the second substrate 41 toward the first substrate 11, and a corresponding portion of the second functional layer 14 concaves in the direction from the second substrate 41 toward the first substrate 11. In this way, the stress applied by the first adhesive layer 12 on the first functional layer 13 and the second functional layer 14 is released, which may reduce the risk of uneven stress on the first functional layer 13 and the second functional layer 14 due to the inconsistent thickness of the first adhesive layer 12.

In a case where the thickness of the third adhesive layer 15 is inconsistent, a thicker portion of the third adhesive layer 15 arches in a direction from the first substrate 11 toward the second substrate 41, and accordingly, a portion of the second functional layer 14 bonded to that portion arches in the direction from the first substrate 11 toward the second substrate 41; and a thinner portion of the third adhesive layer 15 concaves in a direction from the second substrate 41 toward the first substrate 11, and accordingly, a portion of the second functional layer 14 bonded to that portion concaves in the direction from the second substrate 41 toward the first substrate 11. In this way, the stress applied by the third adhesive layer 15 on the first functional layer 13 and the second functional layer 14 is released, which may reduce the risk of uneven stress on the first functional layer 13 and the second functional layer 14 due to the inconsistent thickness of the third adhesive layer 15.

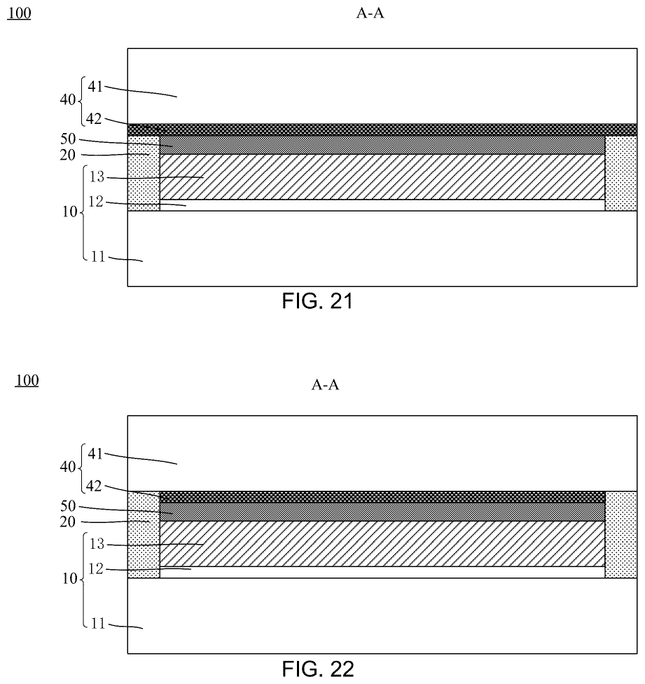

In some embodiments, as shown in FIG. 21, the second stacked structure includes a second substrate 41 and a fourth adhesive layer 42 disposed in stack, in which the fourth adhesive layer 42 is located on a side of the second substrate 41 proximate to the second adhesive layer 50, and the fourth adhesive layer 42 may reduce the risk of the second substrate 41 being broken by external impact of a certain energy or temperature changes. Even if the second substrate 41 is broken, fragments of the second substrate 41 will stick to the fourth adhesive layer 42, thereby reducing the risk of the fragments of the second substrate 41 flying around. The material of the fourth adhesive layer 42 includes EVA, PVB or SGP.

For example, as shown in FIG. 21, an orthographic projection of the fourth adhesive layer 42 on the reference surface coincides with an orthographic projection of the second substrate 41 on the reference surface, and the adhesive frame 20 abuts against the fourth adhesive layer 42. In this way, the fourth adhesive layer 42 covers the second substrate 41. If the second substrate 41 is broken by an external impact of a certain energy or temperature changes, any portion of the second substrate 41 will stick to the fourth adhesive layer 42, reducing the risk of fragments of the second substrate 41 flying around.

Alternatively, for example, as shown in FIG. 22, an orthographic projection of the fourth adhesive layer 42 on the reference surface is located within an orthographic projection of the second substrate 41 on the reference surface, and has a spacing from a boundary of the orthographic projection of the second substrate 41; and the orthographic projection of the fourth adhesive layer 42 on the reference surface coincides with an orthographic projection of the second adhesive layer 50 on the reference surface. In one aspect, the adhesive frame 20 abuts against the second substrate 41, which may reduce the risk of inconsistent spacing between the first substrate 11 and the second substrate 41 due to the inconsistent thickness of the fourth adhesive layer 42. In another aspect, the material of the fourth adhesive layer includes PVB. Since a surface of the adhesive frame 20 formed by the PVB sheet is uneven, there is a small gap between the adhesive frame 20 and the first substrate 11. In the subsequent manufacturing process, the air in the deformation gap 1 between the adhesive frame 20 and the first functional layer 13 may be discharged through the small gap between the adhesive frame 20 and the first substrate 11, thereby avoiding the generation of bubbles in the dimming device 100.

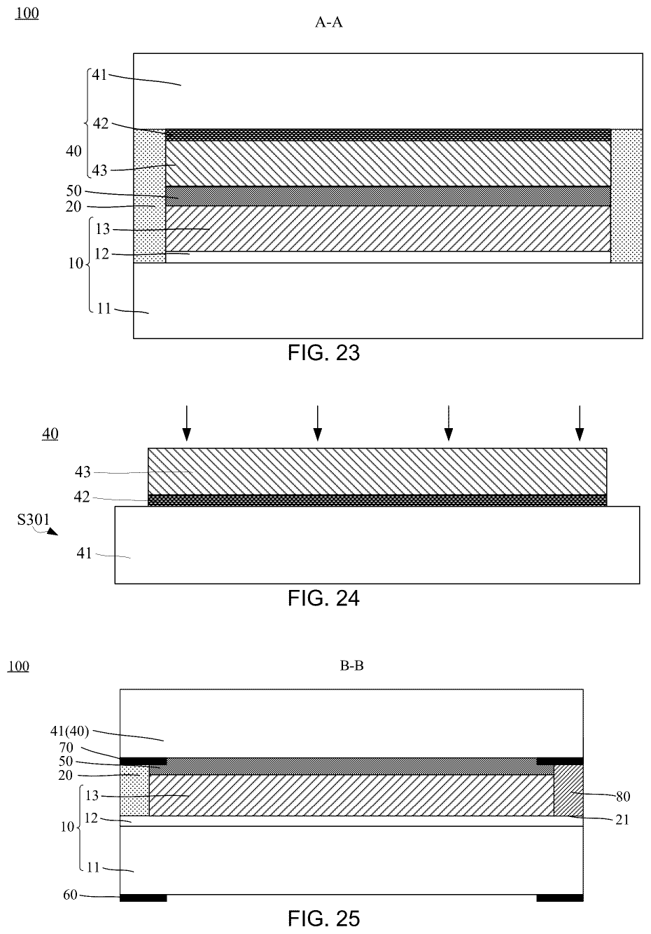

In some other embodiments, as shown in FIG. 23, the second stacked structure 40 includes a second substrate 41, a fourth adhesive layer 42, and a third functional layer 43 disposed in stack. The third functional layer may be a dimming functional layer, a display functional layer or a touch functional layer.

A surface of the second substrate 41 proximate to the third functional layer 43 is bonded to the adhesive frame 20, and the first stacked structure 10 and the third functional layer 43 are provided with a first gap 2 therebetween. An orthographic projection of the fourth adhesive layer 42 on the reference surface is located within an orthographic projection of the second substrate 41 on the reference surface, and has a spacing from a boundary of the orthographic projection of the second substrate 41; and the orthographic projection of the fourth adhesive layer 42 on the reference surface coincides with an orthographic projection of the third functional layer 43 on the reference surface. The adhesive frame 20 further surrounds the third functional layer 43, and the adhesive frame 20 may reduce the risk of water vapor entering the third functional layer 43.

Based on the above embodiments, between S200 (forming the adhesive frame 20 on a side of the first stacked structure 10) and S300 (attaching the second stacked structure 40 on a side of the adhesive frame 20 away from the first substrate 11), the manufacturing method further includes steps (S301 to S302).

As shown in FIG. 24, in S301, pressure is applied to the second stacked structure 40.

There is a small gap between the fourth adhesive layer 42 and the second substrate 41 in the formed second stacked structure 40, and the small gap can accommodate air. Applying pressure to the second stacked structure 40 may remove the air in the small gap between the fourth adhesive layer 42 and the second substrate 41, thereby increasing the bonding area of the fourth adhesive layer 42 and the second substrate 41, and further enabling the fourth adhesive layer 42 to connect the second substrate 41 and the third functional layer 43 more firmly.

In S302, laminating the second stacked structure 40.

The fourth adhesive layer 42 bonds the second substrate 41 and the third functional layer 43, and an orthographic projection of the third functional layer 43 on the reference surface coincides with an orthographic projection of the fourth adhesive layer 42 on the reference surface. Compared to a situation where the orthographic projection of the third functional layer is located within the orthographic projection of the fourth adhesive layer 42 on the reference surface and has a spacing from a boundary of the orthographic projection of the fourth adhesive layer 42, during the process of applying pressure to the second stacked structure 40 and laminating the second stacked structure 40, the entire fourth adhesive layer 42 of some embodiments of the present disclosure is compressed, which enables the thickness of the fourth adhesive layer 42 to be consistent, so that the third functional layer 43 may be subjected to more uniform force.

In some embodiments, the dimming device 100 is applied to vehicle window glass, and the first adhesive layer 12 is closer to the interior of the vehicle than the second adhesive layer 50. As shown in FIG. 25, the dimming device 100 further includes a first light-shielding layer 60 and a second light-shielding layer 70. The first light-shielding layer 60 is located on a side of the first substrate 11 away from the second substrate 41. The first light-shielding layer 60 is arranged along an edge of the first substrate 11. An outer boundary of an orthographic projection of the first light-shielding layer 60 on the first substrate 11 coincides with a boundary of the first substrate 11, and an inner boundary of the orthographic projection of the first light-shielding layer 60 on the first substrate 11 is located within an inner boundary of an orthographic projection of the adhesive frame 20 on the first substrate 11. That is, the inner boundary is closer to the center of the dimming device than an inner boundary of the orthographic projection of the adhesive frame 20 on the reference plane. In this way, the first light-shielding layer 60 covers the adhesive frame 20, and the first light-shielding layer 60 may reduce the risk of ultraviolet light irradiating the adhesive frame 20, reduce the risk of aging of the adhesive frame 20, and increase the service life of the adhesive frame 20.

The second light-shielding layer 70 is located on a side of the second substrate 41 proximate to the first substrate 11. The second light-shielding layer 70 is arranged along an edge of the second substrate 41, and at least a portion of the second light-shielding layer 70 is located between the second substrate 41 and the adhesive frame 20. That is, an outer boundary of an orthographic projection of the second light-shielding layer 70 on the second substrate 41 coincides with a boundary of the second substrate 41; and an inner boundary of an orthographic projection of the second light-shielding layer 70 on the second substrate 41 coincides with an inner boundary of an orthographic projection of the adhesive frame 20 on the reference surface, or the inner boundary is closer to the center of the dimming device than the inner boundary of the orthographic projection of the adhesive frame 20 on the reference plane. In this way, the second light-shielding layer 70 covers the adhesive frame 20, and the second light-shielding layer 70 may reduce the risk of ultraviolet light irradiating the adhesive frame, reduce the risk of aging of the adhesive frame 20, and increase the service life of the adhesive frame 20. The second light-shielding layer 70 is located on a side of the second substrate 41 proximate to the first substrate 11, thereby reducing the risk of objects outside the vehicle scratching the second light-shielding layer 70.

In a case where the dimming device 100 includes the first light-shielding layer 60 and the second light-shielding layer 70, the first light-shielding layer 60 and the second light-shielding layer 70 may further reduce the risk of ultraviolet light irradiating the sealing block 80, reduce the risk of aging of the sealing block 80, and increase the service life of the sealing block 80.

On the basis of the above embodiments, after S700 (sealing the first opening 21), the manufacturing method further includes a step (S800).

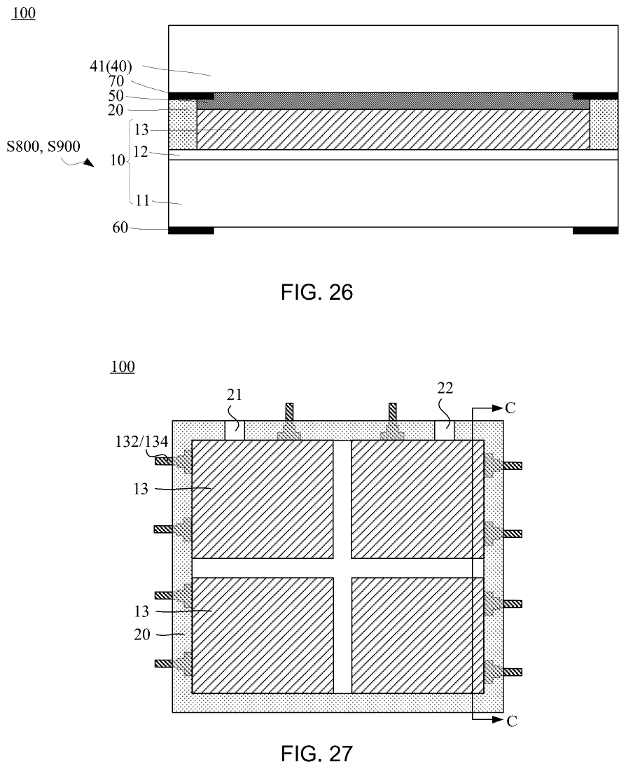

As shown in FIG. 26, in S800, a first light-shielding layer 60 is formed.

The first light-shielding layer 60 is located on a side of the first stacked structure 10 away from the second stacked structure 40 and is arranged along an edge of the first stacked structure 10. An outer boundary of an orthographic projection of the first light-shielding layer 60 on the reference surface coincides with a boundary of an orthographic projection of the first stacked structure 10 on the reference surface, and an inner boundary of the orthographic projection of the first light-shielding layer 60 on the reference surface is closer to the center of the dimming device than an inner boundary of an orthographic projection of the adhesive frame 20 on the reference surface, that is, the first light-shielding layer 60 covers the adhesive frame 20. In this way, the first light-shielding layer 60 may reduce the risk of ultraviolet light irradiating the adhesive frame 20, reduce the risk of aging of the adhesive frame 20, and increase the service life of the adhesive frame 20.

Before S300 (attaching the second stacked structure 40 on a side of the adhesive frame 20 away from the first substrate 11), the manufacturing method further includes a step (S900).

As shown in FIG. 26, in S900, a second light-shielding layer 70 is formed.

The second light-shielding layer 70 is located on a surface of the second substrate 41 and is arranged along an edge of the second substrate 41. During S300 (attaching the second stacked structure 40 on a side of the adhesive frame 20 away from the first substrate 11), the second light-shielding layer 70 is located on a side of the second substrate 41 proximate to the first functional layer 13, which may reduce the risk of scratching the second light-shielding layer 70 by objects outside the vehicle. At least a portion of the second light-shielding layer 70 is located between the second substrate 41 and the adhesive frame 20. That is, an outer boundary of an orthographic projection of the second light-shielding layer 70 on the reference surface coincides with a boundary of an orthographic projection of the second stacked structure 40 on the reference surface; and an inner boundary of the orthographic projection of the second light-shielding layer 70 on the reference surface coincides with an inner boundary of an orthographic projection of the adhesive frame 20 on the reference surface, or the inner boundary is closer to the center of the dimming device than the inner boundary of the orthographic projection of the adhesive frame 20 on the reference surface. In this way, the second light-shielding layer 70 covers the adhesive frame 20. The second light-shielding layer 70 may reduce the risk of ultraviolet light irradiating the adhesive frame, reduce the risk of aging of the adhesive frame 20, and increase the service life of the adhesive frame 20.

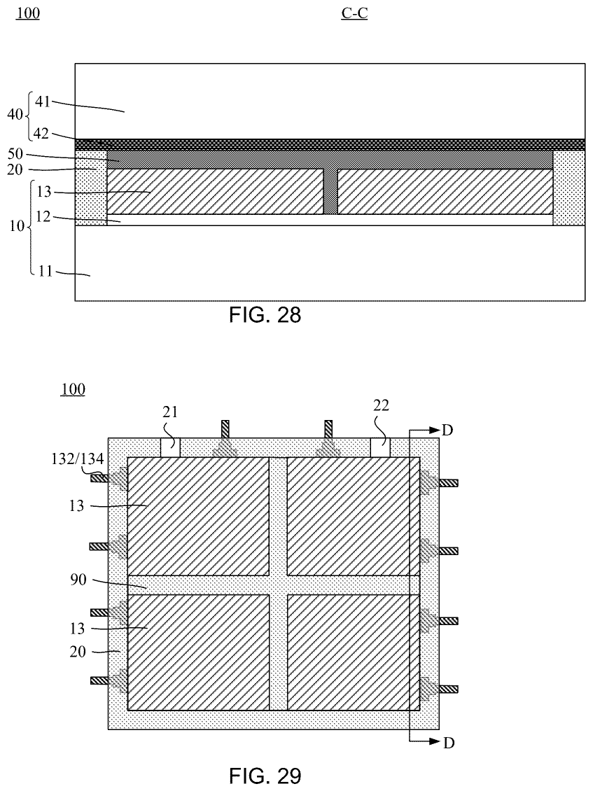

In some embodiments, as shown in FIG. 27 and FIG. 28, there are a plurality of first functional layers 13, and the plurality of first functional layers 13 are all bonded to the first adhesive layer 12. Generally speaking, it is difficult to form a large first functional layer 13, but it is relatively simple to form a small first functional layer 13. Thus, in a case where the dimming device 100 is large in size, the plurality of small first functional layers 13 are used to replace a large first functional layer 13, which may reduce the difficulty of manufacturing the dimming device 100. There is a gap between two adjacent first functional layers 13, so that the risk of collision between the two adjacent first functional layers 13 may be reduced. A portion of the second adhesive layer 50 is located in a space between the two adjacent first functional layers 13.

For example, the plurality of first functional layers 13 are arranged in an array configuration. For example, the plurality of first functional layers 13 are arranged in a rectangular array. For another example, the plurality of first functional layers 13 are arranged in a circular array.

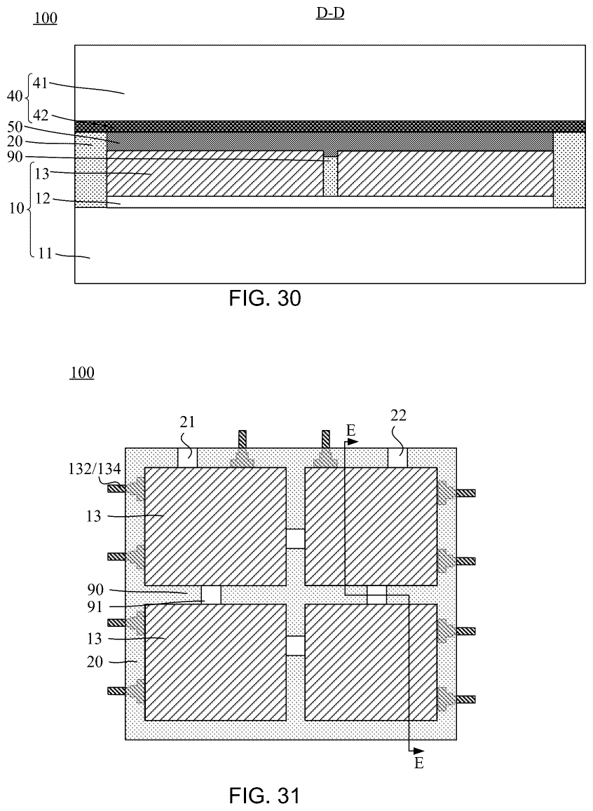

In some embodiments, as shown in FIG. 29 and FIG. 30, the dimming device further includes a limiting strip 90, and a portion of the limiting strip 90 is located in a spacing between two adjacent first functional layers 13. The limiting strip 90 is used to separate the two adjacent first functional layers 13 to reduce the risk of collision between the two adjacent first functional layers 13. The limiting strip 90 and the second stacked structure 40 are provided with a spacing therebetween. In this way, during the process of injecting liquid adhesive into the dimming device 100, the liquid adhesive can fill the first gap between each first functional layer 13 and the second stacked structure 40 through the spacing between the limiting strip 90 and the second stacked structure 40.

For example, a surface of the limiting strip 90 away from the first substrate 11 is higher than a surface of the first functional layer 13 away from the first substrate. Alternatively, for example, the surface of the limiting strip 90 away from the first substrate 11 is substantially flush with the surface of the first functional layer 13 away from the first substrate. Alternatively, for example, the surface of the limiting strip 90 away from the first substrate 11 is lower than the surface of the first functional layer 13 away from the first substrate. In a case where the surface of the limiting strip 90 away from the first substrate 11 is lower than the surface of the first functional layer 13 away from the first substrate, a portion of the second adhesive layer 50 is located in the spacing between two adjacent first functional layers 13.

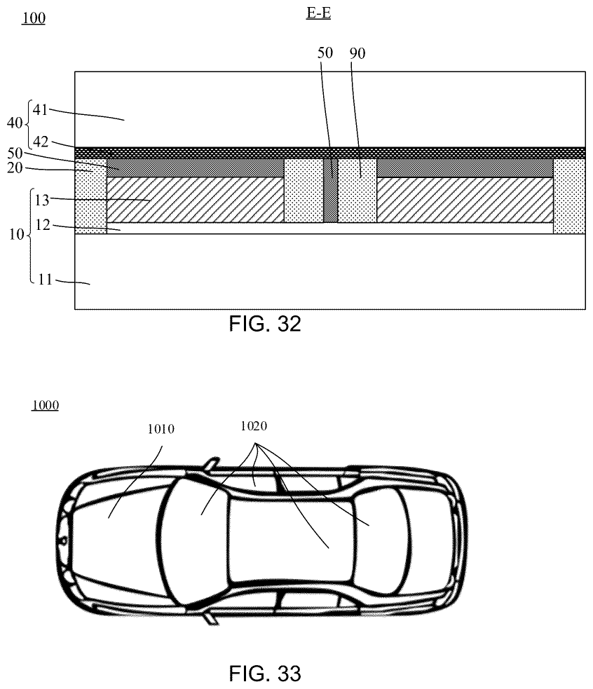

In some other embodiments, as shown in FIG. 31 and FIG. 32, the dimming device further includes a limiting strip 90, and a portion of the limiting strip 90 is located in a spacing between two adjacent first functional layers 13. The limiting strip 90 is used to separate the two adjacent first functional layers 13 to reduce the risk of collision between the two adjacent first functional layers 13. The limiting strip 90 is in contact with the second stacked structure 40, so that the limiting strip 90 may reduce the risk of water vapor in the first functional layer 13 entering the adjacent first functional layers 13. The limiting strip 90 has a plurality of third openings 91, and at least one third opening 91 is located between the two adjacent first functional layers 13. In this way, during the process of injecting liquid adhesive into the dimming device 100, the liquid adhesive may flow through the third opening 91 to the first gap between each first functional layer 13 and the second stacked structure 40, thereby filling the first gap. The liquid adhesive further fills the third openings 91, to enable a portion of the second adhesive layer 50 to be located within the third openings 91.

In some embodiments, the embodiments of the present disclosure further provide a dimming structure. The dimming structure includes a dimming device 100, and the dimming structure is one of a lighting roof, a curtain wall, a rail transportation vehicle, an automobile, and a billboard.

The dimming device 100 may be used in the construction field. For example, the dimming device 100 may be used in a lighting roof or a curtain wall. The dimming device 100 may be used in partition glass. Compared with the use of brick walls to separate rooms in the construction field, the dimming device 100 in the embodiments of the present disclosure is thinner, so the dimming device 100 may save space. A company logo may also be displayed on the partition glass. In this case, the dimming structure including the dimming device 100 may be, for example, a lighting roof, a curtain wall, or the like.

The dimming device 100 may also be applied in the transportation field. For example, the dimming device 100 may be applied in rail transportation vehicles or automobiles. Rail transportation vehicles may include subways, light rails, aerial rail trains, trams, and magnetic levitation trains, which is not enumerated one by one in the embodiments of the present disclosure. Automobiles may include passenger vehicles, commercial vehicles, trucks, or buses, which is not enumerated one by one in the embodiments of the present disclosure. In this case, the dimming structure including the dimming device 100 may be, for example, a rail transportation vehicle or the like.

The implementation of the present disclosure is illustrated by taking the dimming structure being an automobile 1000 as an example. As shown in FIG. 33, the automobile 1000 includes an automobile body 1010 and a vehicle window glass 1020 mounted on the automobile body 1010. The vehicle window glass 1020 may be one or more of front window glass, sunroof glass, rear window glass or side window glass of the automobile. The vehicle window glass 1020 includes the dimming device 100 according to any one of the above embodiments. The dimming device 100 may also be used on a central control touch screen in the automobile 1000.

The dimming device 100 may also be applied in the advertising field. For example, the dimming device 100 may be applied in billboards.

In the description of the present specification, specific features, structures, materials, or characteristics may be combined in any one or more embodiments or examples in a suitable manner.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1-5. (canceled)

6. A dimming device, comprising:
a first stacked structure, comprising a first substrate, a first adhesive layer and a first functional layer disposed in stack;
a second stacked structure, located on a side of the first substrate proximate to the first adhesive layer, the second stacked structure comprising a second substrate;
a second adhesive layer, located between the first stacked structure and the second stacked structure, and configured to bond the first stacked structure and the second stacked structure;
an adhesive frame, located between the first substrate and the second substrate and surrounding the first functional layer and the second adhesive layer, the adhesive frame having at least one first opening, a projection of the at least one first opening along a first direction at least partially overlapping with a projection of the second adhesive layer along the first direction; wherein the first direction is perpendicular to a side surface of the adhesive frame where the at least one first opening is located; and
at least one sealing block, each sealing block in the at least one sealing block being located in a first opening in the at least one first opening and sealing the first opening.

7. The dimming device according to claim 6, wherein a thickness of the first adhesive layer is M×d₁, and a thickness of the adhesive frame is N×d₂; wherein M and N are both positive integers less than 6, and N is greater than M; d₁ and d₂ range from 0.3 mm to 0.5 mm, and d₁ is less than or equal to d₂.

8. The dimming device according to claim 7, wherein a thickness of the first functional layer is d₃, and d₃ is less than or equal to 1.1 mm; and
a thickness of the second adhesive layer is N×d₂-M×d₁-d₃.

9. The dimming device according to claim 6, wherein a material of the adhesive frame is same as a material of the first adhesive layer and different from a material of the sealing block, and the material of the first adhesive layer is different from a material of the second adhesive layer.

10. The dimming device according to claim 6, wherein an orthographic projection of the first adhesive layer on a reference surface is located within an orthographic projection of the first substrate on the reference surface and has a spacing from a boundary of the orthographic projection of the first substrate, and the orthographic projection of the first adhesive layer on the reference surface coincides with an orthographic projection of the first functional layer on the reference surface; and the adhesive frame abuts against the first substrate; wherein the reference surface is parallel to a surface of the first substrate proximate to the first functional layer.

11. The dimming device according to claim 6, wherein an orthographic projection of the first adhesive layer on a reference surface coincides with an orthographic projection of the first substrate on the reference surface, and an orthographic projection of the first functional layer on the reference surface is located within the orthographic projection of the first adhesive layer on the reference surface and has a spacing from a boundary of the orthographic projection of the first adhesive layer; and the adhesive frame abuts against the first adhesive layer; wherein the reference surface is parallel to a surface of the first substrate proximate to the first functional layer.

12. The dimming device according to claim 6, wherein
the first functional layer is a dimming functional layer configured to adjust light transmittance, and a material of the first adhesive layer is polyvinyl butyral (PVB) or sentry glass plus (SGP); or
the first functional layer is a display functional layer configured to display images, and a material of the first adhesive layer is optically clear adhesive (OCA), optical clear resin (OCR), or ethylene vinyl acetate (EVA).

13. The dimming device according to claim 6, wherein the first stacked structure further comprises:
a second functional layer, located on a side of the first functional layer away from the first substrate; and
a third adhesive layer, located between the first functional layer and the second functional layer, and configured to bond the first functional layer and the second functional layer.

14. The dimming device according to claim 6, wherein the second stacked structure further comprises:
a fourth adhesive layer located on a side of the second substrate proximate to the second adhesive layer.

15. The dimming device according to claim 14, wherein an orthographic projection of the fourth adhesive layer on a reference surface coincides with an orthographic projection of the second substrate on the reference surface, and the adhesive frame abuts against the fourth adhesive layer; wherein the reference surface is parallel to a surface of the first substrate proximate to the first functional layer.

16. The dimming device according to claim 14, wherein an orthographic projection of the fourth adhesive layer on a reference surface is located within an orthographic projection of the second substrate on the reference surface, and has a spacing from a boundary of the orthographic projection of the second substrate; the orthographic projection of the fourth adhesive layer on the reference surface coincides with an orthographic projection of the second adhesive layer on the reference surface; and the adhesive frame abuts against the second substrate; wherein the reference surface is parallel to a surface of the first substrate proximate to the first functional layer.

17. The dimming device according to claim 16, wherein the second stacked structure further comprises:
a third functional layer, located on a side of the fourth adhesive layer away from the second substrate, wherein the adhesive frame further surrounds the third functional layer.

18. The dimming device according to claim 6, further comprising:
a first light-shielding layer, located on a side of the first substrate away from the second substrate and arranged along an edge of the first substrate, wherein of an orthographic projection of the first light-shielding layer on the first substrate, an outer boundary coincides with a boundary of the first substrate, and an inner boundary of the first light-shielding layer is located within an inner boundary of an orthographic projection of the adhesive frame on the first substrate; and
a second light-shielding layer, located on a side of the second substrate proximate to the first substrate and arranged along an edge of the second substrate, wherein at least a portion of the second light-shielding layer is located between the second substrate and the adhesive frame.

19. The dimming device according to claim 6, wherein the first functional layer comprises a flexible circuit board, and the flexible circuit board and the first opening are located on a same side of the adhesive frame.

20. The dimming device according to claim 6, wherein the first stacked structure comprises a plurality of first functional layers, and the plurality of first functional layers are all bonded to the first adhesive layer; and two adjacent first functional layers in the plurality of first functional layers are provided with a spacing therebetween.

21. The dimming device according to claim 20, further comprising:
a limiting strip, a portion of the limiting strip being located in the spacing between the two adjacent first functional layers, wherein the limiting strip and the second stacked structure are provided with a spacing therebetween.

22. The dimming device according to claim 20, further comprising:
a limiting strip, a portion of the limiting strip being located in a-the spacing between the two adjacent first functional layers, wherein the limiting strip is in contact with the second stacked structure; and the limiting strip has a plurality of third openings, and at least one of the third openings is located between the two adjacent first functional layers.

23. The dimming device according to claim 6, wherein along a second direction, a dimension of the first opening is less than or equal to half a dimension of the first substrate, wherein the second direction is parallel to the side surface of the adhesive frame where the first opening is located.

24. A dimming structure, comprising the dimming device according to claim 6; and the dimming structure being one of a curtain wall, a lighting roof, a rail transportation vehicle, and a passenger vehicle.

25. The dimming device according to claim 6, wherein the first functional layer comprises a flexible circuit board, and the adhesive frame further has at least one second opening; and
the at least one first opening and the at least one second opening are located on a same side of the flexible circuit board; or the at least one first opening is located on one side of the flexible circuit board, and the at least one second opening is located on opposite side of the flexible circuit board.
